(19) United States
(12) Patent Application Publication
(10) Pub. No.: US 2007/0140099 A1
(43) Pub. Date: Jun. 21, 2007

(54) Read-only magnetic memory device mrom

(76) Inventors: Kars-Michiel Hubert Lenssen, Eindhoven (NL); Hendrik Van Houten, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/529,678

(22) PCT Filed: Sep. 12, 2003
(86) PCT No.: PCT/IB03/04009

§ 371 Date: Dec. 11, 2006

(30) Foreign Application Priority Data
Oct. 3, 2002 (EP) 02079082.0

(51) Int. Cl. G11C 17/02

(52) U.S. Cl. 369/300

(57) ABSTRACT

A storage device has an information carrier part (10) and a read-out part (30). The information carrier part (10) is provided with a pattern of an electro-magnetic material constituting an array of bit locations (11) and the presence or absence of said material at the information plane represents the logical value. The read-out part has a two-dimensional array (31) of electro-magnetic sensor elements that are sensitive to the presence of said electro-magnetic material on a near-field working distance. During manufacture the parts are fixedly coupled and aligned for positioning the bit locations opposite the sensor elements.

The invention relates to a storage device.

The invention further relates to a method for assembling a storage device.

For storage of digital data several types of solid state devices are known, such as semiconductor memory circuits of the RAM, ROM or EPROM type. A promising new type of storage device is the so-called MRAM, a magnetic random access memory, based on a magnetic material and electronic circuitry to set and detect the magnetic state of bit locations of the material.

A magnetic random access memory (MRAM) is known from the article: “A 256kb 3.0V 1T1MTJ Nonvolatile Magnetoresistive RAM by Peter K. Naji et al, as published for the 2001 IEEE International Solid-State Circuits Conference 0-7803-76608-5, ISSCC2001/Session 7/Technology directions: Advanced Technologies/7.6”. The MRAM device has a free magnetic layer for information storage. In the device an array of bit cells is accommodated, the bits cells having an electronic sensor element and a bit location on the free magnetic layer. The magnetic state of the material of the free magnetic layer represents a logical value of the bit location. In a read mode the sensor element is arranged for detecting the magnetic state, in particular via a tunneling magneto-resistive effect (TMR). Current is guided via a tunneling barrier wherein the tunnel probability is influenced by the magnetic state, resulting in a change of the resistance of the sensor element. In a program (or write) mode a strong program current is guided via a programming circuit and causes a magnetic field strong enough to set the magnetic state at the respective bit location in dependence on the program current. It is to be noted that such a MRAM is of a non-volatile type, i.e. the logical values of the bit locations do not change if the device is with or without operating power. Hence the MRAM device is suitable for devices that need to be active shortly after power-on. A problem of the known device is that the value of the bit locations has to be programmed by applying the program current for each individual bit cell, which requires a relatively complex circuitry at each bit cell plus addressing electronics.

Therefore it is an object of the invention to provide a storage system that has an efficient way of providing the logical values of the bit locations.

According to a first aspect of the invention the object is achieved with a storage device as defined in the opening paragraph, comprising an information carrier part and a read-out part, the information carrier part having an information plane that is provided with a pattern of an electro-magnetic material constituting an array of bit locations, the presence or absence of said material at the information plane representing a value of a bit location, and the read-out part having an interface surface for cooperating with the information plane, which interface surface is provided with a two-dimensional array of electro-magnetic sensor elements that are sensitive to the presence of said electro-magnetic material on a near-field working distance, the parts being fixedly coupled and aligned for positioning the bit locations opposite the sensor elements substantially at the near-field working distance between a bit location and the corresponding sensor element.

According to a second aspect of the invention the object is achieved with a method of assembling a storage device as defined in the opening paragraph, the device comprising an information carrier part and a read-out part, the information carrier part having an information plane that is provided with a pattern of an electro-magnetic material constituting an array of bit locations, the presence or absence of said material at the information plane representing a value of a bit location, and the read-out part having an interface surface for cooperating with the information plane, which interface surface is provided with a two-dimensional array of electro-magnetic sensor elements that are sensitive to the presence of said electro-magnetic material on a near-field working distance, which method comprises aligning the information carrier part and the read-out part for positioning the bit locations opposite the sensor elements substantially at the near-field working distance between a bit location and the corresponding sensor element, and, while being aligned, physically bonding the information carrier part and the read-out part.

The effect is that a storage device having a predefined content can be produced at a relatively low cost. The values of the bit locations on the information carrier are constituted by the absence or presence of material. The information carrier part can be manufactured by mechanical techniques such as embossing or pressing. The read-out part can be a standardized part manufactured in large numbers to be combined with different information carrier parts. The sensor elements are different from MRAM cells in that they detect the presence of the material by generating a magnetic or electric field and are sensitive to the disturbance thereof caused by the material. Further the sensor elements will be less complex then the usual bit cell elements in an MRAM device, because no writing circuitry is needed. Alignment is only required during the final step of bonding the information carrier part to the read-out part. Hence the total cost of the device according to the invention will be substantially lower then an MRAM device of the same data storage capacity. The advantage of having a fixed information carrier in combination with a read-out part is that for a user the contents of the device are immediately available, and can be accessed at high speed without any scanning process, such as necessary for an optical disc. The device provides an inexpensive replicable solid-state memory. The concept combines some advantages of non-volatile solid-state storage (rapid random access, high data rate, low power, robustness and insensitivity to shock due to the absence of moving parts) with the advantages of optical storage (availability of inexpensive replicable memory carrier, suitable for the distribution of digital content). In addition there is an inherent protection against copying the content, because the user will not have access to a similar storage device of a writable type.

The invention is also based on the following recognition. The known magnetic storage device is a solid state device that contains the information plane. In such a solid state device the information plane is not accessible, and is manufactured together with the sensor elements. Programming the contents of the bit locations has to be performed by the bit cell sensor element itself. The inventors have seen that the information plane may be manufactured separately. The effect is achieved by separating the read-out functionality and the storage functionality into two physically distinct parts during manufacturing. At the end of the production, the information carrier part is attached, i.e. aligned and fixed, to the solid-state reader. Since this takes place in a clean room, contamination of the interface surface can be controlled to be low. In MRAM type devices data is stored in the magnetic state of magnetic material that is effectively hard enough two have two meta-stable states of magnetization. The inventors have used a material that is called electro-magnetic in this document because its presence or absence is detectable via an electrical and/or magnetic field (also called bias field) generated by a reading element. It is noted that the detection of the value of a bit location does not depend on the magnetic state of the material, but on the presence or absence of the material itself. An electro-magnetic sensor element can generate the bias field and can detect disturbances in the field extending over a predefined near-field working distance, which is in practice in the same order of magnitude as the minimum dimensions of the bit location. Alignment is required to bring the elements opposite and close to the bit locations within the near-field working distance. Further any principle of near-field coupling can be used that is based on electro-magnetic fields, e.g. optical, electrostatic, or magnetostatic.

In an embodiment of the device the pattern at the information plane is constituted by a layer of the electro-magnetic material on a substrate having protruding portions or depressed portions that bring the electro-magnetic material of the layer either outside or inside the near-field working distance. This has the advantage that the substrate can be easily manufactured using stamping and that a continuous layer can be applied covering the entire surface.

Further preferred embodiments of the device according to the invention are given in the dependent claims.

These and other aspects of the invention will be apparent from and elucidated further with reference to the embodiments described by way of example in the following description and with reference to the accompanying drawings, in which

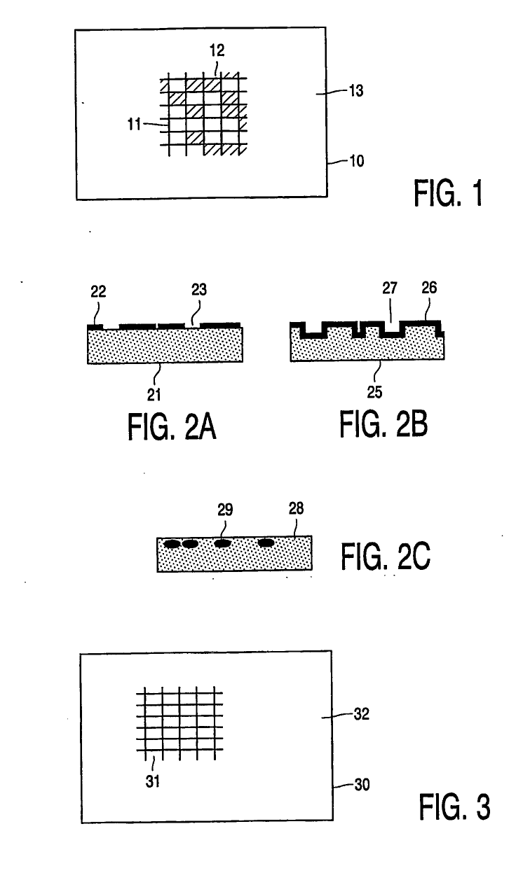

FIG. 1 shows an information carrier part (top view),

FIG. 2a shows a patterned information carrier part,

FIG. 2b shows an embossed information carrier part,

FIG. 2c shows an information carrier part having embedded particles,

FIG. 3 shows a read-out part,

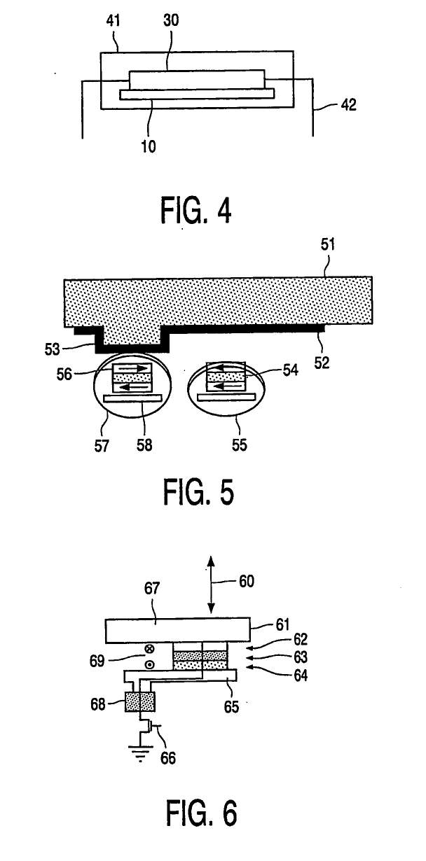

FIG. 4 shows a storage device,

FIG. 5 shows a sensor elements at a near field working distance of an information plane, and

FIG. 6 shows a sensor element in detail.

In the Figures, elements which correspond to elements already described have the same reference numerals.

FIG. 1 shows an information carrier part (top view). An information carrier part 10 has an information plane that is provided with a pattern of an electro-magnetic material 12 constituting an array of bit locations 11. The presence or absence of the material 12 at the information plane provides a physical parameter for representing a value of a bit location. It is noted that the information plane is situated on a top surface 13 of the information carrier part 10. The top surface 13 of the information carrier part is intended to be coupled to an interface surface of a read-out part. The information plane is considered to be present at an effective distance from the mechanical top layer, e.g. a thin cover layer for protecting the information plane may constitute the outer layer of the information carrier part. Further it is noted that material away from the top surface 13 and outside a near-field working distance of an intended read-out part is not considered part of the information plane. Sensor elements in said read-out part are placed near the information plane, but some intermediate material like bonding material or contamination may be present in between. Hence the effective distance is determined by any intermediate material and the intended read-out sensor elements that have a near-field working distance extending outward from the interface surface towards the information plane. The physical effect of the presence or absence of material at the information plane for reading the information is explained below with reference to FIG. 5.

FIG. 2a shows a patterned information carrier part in a cross section view. The information carrier has a substrate 21. An information plane is constituted on the top side of the substrate 21 by a pattern of electro-magnetic material, the pattern constituting an array of bit locations. In a first bit location 22 the material is present for example indicating the logic value 1, and in a second bit location 23 the material is absent for example indicating a logic value 0. The material has a soft magnetic property for being detectable by said sensor elements. The pattern of material can be applied by well known manufacturing methods for patterned magnetic media, although it is to be noted that no permanent magnetizations are required. Suitable methods are sputtering and locally etching, ion beam patterning or pressing using a mask.

FIG. 2b shows an embossed information carrier part in a cross section view. The information carrier has a substrate 25. An information plane is constituted on the top side of the substrate 25 by a continuous layer of electro-magnetic material that has protruding and depressed portions. The shape of the layer constitutes an array of bit locations. In a first bit location 26 the material is present by a protruding portion within the near-field working distance of the intended read-out unit, for example indicating the logic value 1. In a second bit location 27 the material is absent from the information plane by a depressed portion which brings the material outside the near-field working distance, for example indicating a logic value 0. The embossed pattern can be applied to the substrate (or to the layer itself) by well known manufacturing methods, like pressing using a stamp similar to producing optical discs of the CD type. For example for production first fabricate a resist mask on a bare Si wafer by means of electron-beam lithography and use this as a master. If desired, holes are etched in the Si for storing the information in the 2D hole pattern. Then, using the master, replicate the pattern on a foil, or via injection moulding, or via embossing, or via 2P. Then deposit a thin magnetic layer (e.g. via sputtering) on the replica, and, optionally, magnetize the material in a uniform external magnetic field. It is to be noted that there are various possibilities for the exact operation principle. The information plane merely functions as a flux guide (using soft-magnetic material, and hence no magnetization step required); the information plane uses shape anisotropy, resulting e.g. in a perpendicular magnetization of the inverted holes; or the information plane has been magnetized uniformly, resulting in stray fields at the edges of the holes. The first principle, as further described with FIG. 5, has the advantage that it is most simple to realize, and it circumvents the limitations on bit size imposed by the super paramagnetic limit.

FIG. 2c shows an information carrier part having embedded particles in a cross section view. The information carrier has a substrate 28. An information plane is constituted at the top side of the substrate 28 by embedding particles 29. At a bit location there is either a particle of the material embedded or no particle, indicating the logical value. The particles present the material within the near-field working distance of the intended read-out unit. Obviously, instead of embedding a single particle at a bit location, a number of smaller particles may be used also. The information carrier is manufactured by incorporating a pattern of beads in the substrate or attaching beads to the substrate using a glue mask. Alternatively the beads can be positioned by applying spatially modulated magnetic fields.

FIG. 3 shows a read-out part. The read-out part 30 is intended to cooperate with the information carrier parts described above. Thereto the read-out part has an interface surface 32. The interface surface 32 is provided with an array 31 of sensor elements. The array is a two-dimensional layout of electro-magnetic sensor units that are sensitive to the presence of said electro-magnetic material on a near-field working distance.

It is noted that several combinations of an electro-magnetic material and a sensor element can be chosen. In an embodiment the sensor elements are provided with circuitry for generating a magnetic field and detecting the magnetic field as influenced by the presence of absence of the material having a soft magnetic property. In another embodiment the sensor elements are provided with circuitry for generating an electrical field and detecting the electrical field as influenced by the presence or absence of the electro-magnetic material, e.g. via capacitive coupling. In another embodiment the sensor elements are provided with circuitry for generating a fluctuating magnetic field and detecting the magnetic field as influenced by the presence of absence of a conductive material via eddy currents. In another embodiment the sensor elements are arranged for emitting light as the electro-magnetic field and detecting the effect of the material on a near-field working distance from the source of light. The further embodiments described below are based on using magnetic material. A suitable material is a soft magnetic material and a suitable sensor element is based on the magneto-resistive effect. An example is described below with reference to FIG. 6.

FIG. 4 shows a storage device. The storage device has a housing 41 that contains the information carrier part 10 and the read-out part 30. Electrical connectors 42 extend from the housing 41 for connecting the storage device to the outside world. As shown the parts are fixedly coupled inside the housing. During manufacture both parts are aligned for positioning the bit locations opposite the sensor elements substantially at the near-field working distance between a bit location and the corresponding sensor element. The parts are bonded together in the aligned state, e.g. by applying glue or by the encapsulation process that forms the housing. It is noted that because the memory layer is added as a last step and the reader device can be manufactured in large numbers, the manufacture of the new device leads to economies of scale. The memory layer can be replicated in desired numbers in a separate production line, and can then be bonded to the reader chips using for example a wafer bonding process.

FIG. 5 shows sensor elements at a near field working distance of an information plane. Two sensor elements 54, 56 of the array are shown. Above the sensor elements 54, 56 an information carrier part is shown having a substrate 51 and a layer of a magnetic material 52. At a bit location 53 a protruding portion brings the material close to the sensor element 56 and into its near-field working distance. At the adjacent bit location the material is outside the near-field working distance of the next sensor element.54. The sensor elements are arranged for generating magnetic fields 55, 57, for example as shown by guiding an electric current via a lead 58 beneath the element 56. The magnetic field is influenced by the absence or presence of the magnetic material as shown in the resulting magnetic fields 55,57, which result in a different magnetic direction in a top layer of the sensor element. The direction is detected in sensor elements having a multilayer or single layer stack by using a magneto-resistive effect, for example GMR, AMR or TMR. The TMR type sensor is preferred for resistance matching reasons for the read-only sensor element of this invention.

As shown in the Figure the vicinity of a portion of the magnetic layer on the information carrier forces the field lines of a bias field away from the TMR-element. The material acts as a flux guide: the field lines go through the material instead of through the free layer of the spin-tunnel junction. If the stack of the spin-tunnel junction is designed such that the interlayer magnetostatic coupling results in an antiparallel magnetization configuration if no external magnetic field is applied, the vicinity of a protrusion of the magnetic layer results in a high resistance, while otherwise the bias field will cause a low resistance state. In an embodiment a current carrying conductor is used as field generating strap for the bias field. Alternatively this may be a permanent magnet. Many variants are possible for the bias fields and also stray fields may be used, as will be clear for the person skilled in the art. The bias field in the media can be in the plane of the substrate (as shown in the Figure), but one could alternatively also consider bias fields perpendicular to the substrate resulting in stray fields from the magnetic layer that have components in the plane of the layers of the spin-tunnel junctions. While the given examples use magnetoresistive elements with in-plane sensitivity it is also possible to use elements that are sensitive to perpendicular fields. For a further description of sensors using magnetoresistive effects refer to “Magnetoresistive sensors and memory” by K.-M. H. Lenssen, as published in “Frontiers of Multifunctional Nanosystems”, page 431-452, ISBN 1-4020-0560-1 (HB) or 1-4020-0561-X (PB).

In the storage system data are represented by magnetization directions occurring at a sensor element due to the bit location opposite the sensor on the information plane. The read-out is done by a resistance measurement which relies on a magnetoresistance (MR) phenomenon detected in a multilayer stack. Sensors can be based on the anisotropic magnetoresistance (AMR) effect in thin films. Since the amplitude of the AMR effect in thin films is typically less than 3%, the use of AMR requires sensitive electronics. The larger giant magnetoresistance effect (GMR) has a larger MR effect (5 à 15%), and therefore a higher output signal. The magnetic tunnel junctions use a large tunnel magnetoresistance (TMR) effect, and resistance changes up to ≈50% have been shown. Because of the strong dependence of the TMR effect on the bias voltage, the useable resistance change in practical applications is at present around 35%. In general, both GMR and TMR result in a low resistance if the magnetization directions in the multilayer stack are parallel and in a high resistance when the magnetizations are oriented antiparallel. In TMR multilayers the sense current has to be applied perpendicular to the layer planes (CPP) because the electrons have to tunnel through the barrier layer; in GMR devices the sense current usually flows in the plane of the layers (CIP), although a CPP configuration might provide a larger MR effect, but the resistance perpendicular to the planes of these all-metallic multilayers is very small. Nevertheless, using further miniaturization, sensors based on CPP and GMR are possible.

FIG. 6 shows a sensor element in detail. The sensor has a bit line 61 of an electrically conductive material for guiding a read current 67 to a multilayer stack of layers of a free magnetic layer 62, a tunneling barrier 63, and a fixed magnetic layer 64. The stack is build on a further conductor 65 connected via a selection line 68 to a selection transistor 66. The selection transistor 66 couples said read current 67 to ground level for reading the respective bit cell when activated by a control voltage on its gate. The magnetization directions 69 present in the fixed magnetic layer 64 (also called pinned layer) and the free magnetic layer 62 determine the resistance in the tunneling barrier 63, similar to the bit cell elements in an MRAM memory. The magnetization in the free magnetic layer is determined by the material at the bit location opposite the sensor as described above with FIG. 5, when such material is within the near-field working distance indicated by arrow 60.

In an embodiment no additional means are needed to generate the bias field, but the bias field is effectively built-in in the spin-tunnel junction. This might, for example, be accomplished in the following ways. A built-in permanent magnet is achieved by an additional hard-magnetic layer underneath or above the spin-tunnel junction, or by an “over-dimensioned” pinned layer, e.g. an exchange-biased layer, or the hard-magnetic layer in the case of a “pseudo-spin valve” like MR-element. It is important that the resulting magnetostatic coupling dominates any direct exchange coupling between pinned and free layer, as is generally the case for a spin-tunnel junction. The effect of the magnetostatic coupling on the free layer should be reduced sharply when the soft-magnetic layer of the information carrier is close to the element, i.e. inside the near-field working distance. This can be accomplished by making the distance sufficiently small and the thickness of this layer sufficiently large. In an embodiment the material in the information plane is permanently magnetized in a direction parallel to the magnetization direction of the free layer in the sensor element. Because of flux closure protrusions in the information carrier will lead to a reversal of the magnetization of the free layer, provided the coupling to the carrier is stronger than the coupling with the other layers within the MR element.

For the sensor elements, because of the different requirements compared to those for MRAM, the composition and characteristics of the spin-tunnel junctions are adapted compared to those used for MRAM. While for MRAM two stable magnetization configurations (i.e. parallel and antiparallel) are essential for the storage, this does not have to be the case for the proposed sensor element. Here read sensitivity is crucial, while a bi-stable magnetization configuration is in general not relevant. Of course the direction of the reference magnetization, e.g. in the pinned or exchange-biased layer should be invariant. Hence for the free layer, which acts as detection layer, materials with a low coercivity can be chosen.

In an embodiment a number of sensor elements are read at the same time. The addressing of the bit cells is done by means of an array of crossing lines. The read-out method depends on the type of sensor. In the case of pseudo-spin valves a number of cells (N) can be connected in series in the word line, because the resistance of these completely metallic cells is relatively low. This provides the interesting advantage that only one switching element (usually a transistor) is needed per N cells. The associated disadvantage is that the relative resistance change is divided by N. The read-out is done by measuring the resistance of a word line (with the series of cells), while subsequently a small positive plus negative current pulse is applied to the desired bit line. The accompanying magnetic field pulses are between the switching fields of the two ferromagnetic layers; thus the layer with the higher switching field (the sensing layer) will remain unchanged, while the magnetization of the other layer will be set in a defmed direction and then be reversed. From the sign of the resulting resistance change in the word line it can be seen whether a ‘0’ or a ‘1’ is stored in the cell at the crossing point the word and the bit line. In an embodiment spin valves with a fixed magnetization direction are used and the data is detected in the other, free magnetic layer. In this case the absolute resistance of the cell is measured. In an embodiment the resistance is measured differentially with respect to a reference cell. This cell is selected by means of a switching element (usually a transistor), which implies that in this case one transistor is required per cell. Besides sensors with one transistor per cell, alternatively sensors without transistors within the cell are considered. The zero-transistor per cell sensor elements in cross-point geometry provide a higher density, but have a somewhat longer read time.

The memory device according to the invention is in particular suitable for the following applications. A first application is a portable device that needs exchangeable memory, e.g. a laptop computer or portable music player. The storage device has low power consumption, and instant access to the data. The device can also be used as a storage medium for content distribution. A further application is a smartcard. Also the device can be applied as secure memory that cannot be rewritten after the production. In an embodiment the device also has normal RAM memory in addition to the new memory cells. The new memory array part of the memory device is applied as memory that contains an operating system, program code, etc.

A further application is a memory that is very well copyright-protected. The protection benefits from the fact that no recordable/rewritable version of the information storage device exists and a consumer reasonably cannot copy the bonded read-only information carrier. For example this type of memory is suitable for game distribution. In contrast to existing solutions it has all the following properties: easily replicable, copy-protected, instant-on, fast access time, robust, no moving parts, low power consumption, etc.

Although the invention has been mainly explained by embodiments using soft magnetic material and flux guidance, any type of near-field interaction can be used, e.g. capacitive coupling. It is noted, that in this document the verb ‘comprise’ and its conjugations do not exclude the presence of other elements or steps than those listed and the word ‘a’ or ‘an’ preceding an element does not exclude the presence of a plurality of such elements, that any reference signs do not limit the scope of the claims, that the invention may be implemented by means of both hardware and software, and that several ‘means’ or ‘units’ may be represented by the same item of hardware or software. Further, the scope of the invention is not limited to the embodiments, and the invention lies in each and every novel feature or combination of features described above.

1. Storage device comprising an information carrier part and a read-out part,
the information carrier part having an information plane that is provided with a pattern of an electro-magnetic material constituting an array of bit locations, the presence or absence of said material at the information plane representing a value of a bit location, and
the read-out part having an interface surface for cooperating with the information plane, which interface surface is provided with a two-dimensional array of electro-magnetic sensor elements that are sensitive to the presence of said electro-magnetic material on a near-field working distance,
the parts being fixedly coupled and aligned for positioning the bit locations opposite the sensor elements substantially at the near-field working distance between a bit location and the corresponding sensor element.

2. Device as claimed in claim 1, wherein the pattern at the information plane is constituted by a layer of the electro-magnetic material on a substrate having protruding portions or depressed portions that bring the electro-magnetic material of the layer either outside or inside the near-field working distance.

3. Device as claimed in claim 1, wherein the pattern at the information plane is constituted by a substrate covered by a pattern of areas of said electro-magnetic material, or by the presence or absence of electro-magnetic particles embedded in a substrate.

4. Device as claimed in claim 1, wherein the electro-magnetic material has a soft magnetic property for being detectable by said sensor elements.

5. Device as claimed in claim 1, wherein the electro-magnetic material has an electrically conductive property for being detectable by said sensor elements.

6. Device as claimed in claim 1, wherein the sensor elements are arranged for generating an electro-magnetic field and detecting the presence of said electro-magnetic material in at least one of the following ways:
generating a magnetic field and detecting the magnetic field as influenced by the presence of absence of the electro-magnetic material via a soft magnetic property; or
generating an electrical field and detecting the electrical field as influenced by the presence or absence of the electro-magnetic material via a capacitive coupling; or
generating a fluctuating magnetic field and detecting the magnetic field as influenced by the presence of absence of the electro-magnetic material via eddy currents.

7. Information carrier part for use in the device as claimed in claim 1, characterized in that the information carrier part comprises
an information plane that is provided with a pattern of an electro-magnetic material constituting an array of bit locations, the presence or absence of said material at the information plane representing a value of a bit location.

8. Read-out part for use in the device as claimed in claim 1, characterized in that the read-out part has an interface surface for cooperating with the information plane, which interface surface is provided with a two-dimensional array of electro-magnetic sensor elements that are sensitive to the presence of said electro-magnetic material on a near-field working distance.

9. Method of assembling a storage device comprising an information carrier part and a read-out part as claimed in claim 1,
the information carrier part having an information plane that is provided with a pattern of an electro-magnetic material constituting an array of bit locations, the presence or absence of said material at the information plane representing a value of a bit location, and
the read-out part having an interface surface for cooperating with the information plane, which interface surface is provided with a two-dimensional array of electro-magnetic sensor elements that are sensitive to the presence of said electro-magnetic material on a near-field working distance,
which method comprises
aligning the information carrier part and the read-out part for positioning the bit locations opposite the sensor elements substantially at the near-field working distance between a bit location and the corresponding sensor element, and,
while being aligned, physically bonding the information carrier part and the read-out part.
